(19) United States
(12) Patent Application Publication
(10) Pub. No.: US 2006/0216869 A1
(43) Pub. Date: Sep. 28, 2006

(54) Lithographic apparatus, device manufacturing method, code reading device and substrate

(75) Inventors: Cornelis David Huizer, Rossum (Gld) (NL); Paulus Wilhelmus Leonardus Van Dijk, Eindhoven (NL)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 11/085,228

(22) Filed: Mar. 22, 2005

(51) Int. Cl. H01L 21/82; B44C 1/17

(52) U.S. Cl. 438/129; 156/240

(57) ABSTRACT

A two-dimensional mark has an array of pixels, and one or more reference marks. The array of pixels is used to encode an identifier for the substrate and/or any other desired information. In an embodiment, the array is 8 by 8 pixels providing 264 unique symbols, assuming a binary system wherein each pixel may be in one of two states.

### FIELD

The present invention relates to a lithographic apparatus, a device manufacturing method, a code reading device and a method for manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In the manufacture of devices using lithographic processes, a substrate must undergo a large number of processing cycles, perhaps 20 to 30, with each cycle usually comprising coating the substrate with resist, exposing a pattern onto the resist, developing the resist, performing a process step such as an etch or deposition, and stripping the residual resist. Some of these process steps may involve several sub-process steps. Since various of these process steps for each cycle are carried out by different apparatus, it may be advantageous to keep track of each substrate throughout the cycle. This may be particularly advantageous since, to maximize use of expensive processing equipment, many different batches of substrates will be circulating within a fab at a given time.

### SUMMARY

A way to keep track of substrates is to employ substrate carriers with identifying tags, e.g. RFID tags. Since each carrier will hold several substrates, it is important in when using these kinds of substrate carriers that substrates are returned to the correct slot in the carrier after each step. Mistakes may occur and so it is therefore desirable to have an identifier attached to the substrate itself. However there may be one or more difficulties with this. The identifier should be robust enough to survive the process steps that will be used to form the device, many of which may be highly aggressive. Thus a desired method of applying an identifier would be to use a lithographic process to print the identifier into the substrate, e.g. by etching. However, to print the identifier, a unique mask per substrate, or a unique job definition per substrate using a mask carrying a plurality of different identifiers, would be used. Both options may be time-consuming and expensive. Further, applying an identifier to a substrate may cause a conflict between printing the identifier large enough to be reliably machine-readable but small enough not to use up significant real-estate on the substrate so as to limit the number of dies per substrate. An identifier printed on the substrate should also be reliably located and read, even after possible damage by subsequent process steps. In addition or alternatively, the foregoing considerations are applicable to providing other information on the substrate even though it does not identify the substrate, e.g., process information, time and date information, etc.

Accordingly, it would be advantageous, for example, to provide a novel way of uniquely identifying substrates and/or including other information on the substrate.

According to an aspect of the invention, there is provided a lithographic apparatus arranged to transfer a substrate pattern from a patterning device onto a substrate, comprising a programmable patterning device arranged to transfer a pattern representing a code mark to the substrate.

According to an aspect of the invention, there is provided a device manufacturing method, comprising:

transferring a pattern representing a code mark to a substrate using a programmable patterning device; and

transferring a substrate pattern from a patterning device onto the substrate.

According to an aspect of the invention, there is provided a code reading device arranged to read a code mark on a substrate, the code mark comprising a pixel array and one or more reference markers.

According to an aspect of the invention, there is provided a substrate having printed thereon a code mark comprising a pixel array and one or more reference markers.

According to an aspect of the invention, there is provided a lithographic apparatus arranged to transfer a pattern from a patterning device onto a substrate, wherein the patterning device is a programmable patterning device and the pattern represents a code mark to the substrate.

According to an aspect of the invention, there is provided a device manufacturing method comprising transferring a pattern from a patterning device onto a substrate, wherein the patterning device is a programmable patterning device and the pattern represents a code mark to the substrate.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention; and

FIG. 2 depicts a two-dimensional code array according to an embodiment of the invention.

### DETAILED DESCRIPTION

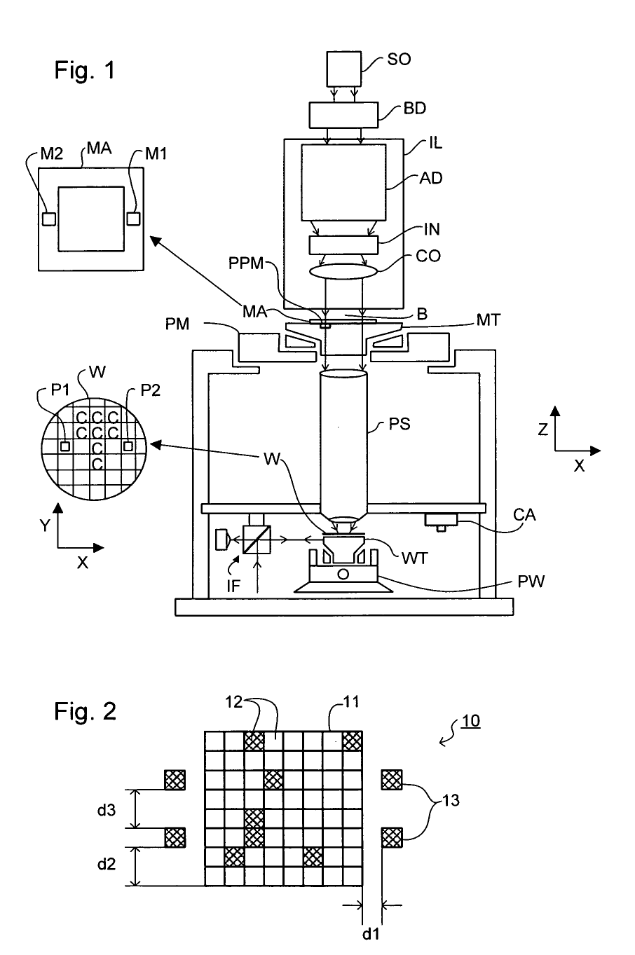

FIG. 1 schematically depicts a lithographic apparatus according to one embodiment of the invention. The apparatus comprises:

an illumination system (illuminator) IL configured to condition a radiation beam B (e.g. UV radiation or DUV radiation).

a support structure (e.g. a mask table) MT constructed to support a patterning device (e.g. a mask) MA and connected to a first positioner PM configured to accurately position the patterning device in accordance with certain parameters;

a substrate table (e.g. a wafer table) WT constructed to hold a substrate (e.g. a resist-coated wafer) W and connected to a second positioner PW configured to accurately position the substrate in accordance with certain parameters; and

a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables (and/or two or more support structures). In such “multiple stage” machines the additional tables or support structures may be used in parallel, or preparatory steps may be carried out on one or more tables or support structures while one or more other tables or support structure are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WT can be moved accurately, e.g. so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus could be used in at least one of the following modes:

1. In step mode, the support structure MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

A two-dimensional code mark 10 according to an embodiment of the invention is shown in FIG. 2. The mark 10 comprises an array 11, the array comprising pixels 12, and one or more reference marks 13.

The array 11 of pixels 12 is used to encode an identifier for the substrate and/or any other desired information. In an embodiment as shown, the array is 8 by 8 pixels providing 264 unique symbols, assuming a binary system wherein each pixel may be in one of two states. Of course more or fewer pixels may be used depending on the amount of information to be encoded. The pixel array 11 need not be square but may be any convenient shape, even a linear array or an irregular shape. It provides a compact marker with high information density.

The one or more reference markers 13 serve to locate the grid and its boundaries to allow precise location of the mark 10 and correct reading. The general location of the mark 10 should be known in advance. The distances d1, d2 between the reference markers 13 and the array 11 and the distance d3 between the reference markers themselves are known in advance so that location of one or more of the reference marks 13 enables one or more boundaries of the array 11 to be determined.

The dimensions of the pixels and reference marker(s) may be selected according to the specific application and in general is a compromise between readability and the availability of space on the substrate. In an embodiment, each pixel is square and has sides typically in the range of, but not limited to, from 3 to 15 μm. In an embodiment, one or more reference markers 13 are of the same size and shape as the pixels 12. In an embodiment, the code mark has overall dimensions less than about 200 μm on the substrate.

The two distinguishable states for each pixel 12 of the mark 10 can be formed by any convenient process, for example by localized etching. For example, localized etching provides a robust mark 10 and allows the mark 10 to be created concurrently with the printing of zero layer alignment marks. Another method of distinguishing the two pixel states is to selectively deposit a reflective and/or absorptive layer. Localized areas of a metal reflective layer can be detected under one or more subsequent layers using radiation, e.g. infra-red, to which one or more subsequent layers are transparent.

The information coded in the mark 10 may be a simple identification number or may include other information such as a time and date stamp, a machine identifier, or one or more process conditions and/or recipes that have been or are to be applied to the substrate. To encode this information, techniques known from the field of communications may be used. For example, the code may include error detection and/or correction schemes such as parity digits or cyclic redundancy codes. The coding need not use the entire symbol space provided by the mark 10 but rather only a subset of possible signals that are less likely to be confused in the event of reading errors or damage to the mark.

Any known technique may be used to print the mark 10 on the substrate but in an embodiment of the invention, a programmable patterning device PPM, such as an LCD panel or digital mirror array, is provided on a support structure MT. With a one-to-one correspondence between pixels in the programmable patterning device PPM and pixels in the mark 10 and with the reduction magnification of the projection system PS, many readily available devices can be used. Use of a programmable patterning device PPM avoids the need to provide a unique mask or job definition for each code to be printed on the substrate—a code number can easily be provided to the programmable patterning device PPM for each mark 10 to be printed. If desired, an entirely self-contained mark printing device can be provided by arranging the programmable patterning device PPM to print a code comprising a machine identifier and a time and date stamp or an automatically incrementing serial number. If a programmable patterning device is used in the lithographic apparatus instead of a mask, the code can easily be incorporated into the pattern to be printed. A programmable patterning device to print the mark 10 can also be used easily to reprint the code mark, or print a new code mark, in the event that the original mark has been damaged or covered by subsequent processes. In an embodiment, the programmable patterning device PPM may be an apparatus that uses an imprint technique to print the mark 10.

To read the mark, in an embodiment, a simple camera CA may be employed. The camera may have a suitable magnifying lens and auto-focus capabilities. Pattern recognition software may be used to decode the image of the mark 10. If the different pixel states of the mark 10 are defined by local etching or deposition, an existing level (focus) sensor may be scanned across the mark to read it out. The precision of such a sensor may allow the use of multiple states, defined by different heights, per pixel, allowing more information to be encoded in the same space. If the different pixel states are defined by different reflectivities, then it may be possible to use the intensity of the returning signal from any substrate sensor, such as an alignment or level sensor, to read out the mark.

Since the requirements for the mark 10 may be different, in particular less exacting, than those of the zero-layer marks or other process layers, a separate patterning apparatus (e.g., an optical or imprint apparatus) optimized to the printing of marks 10 may be provided.

A mark reading device may be provided in each lithographic apparatus to enable, for example, identification of a substrate prior to the performance of an exposure step. In addition or alternatively, a mark reading may be provided in or with other types of process apparatus and qualifying and measurement tools. Stand-alone devices configured to read marks 10 may also be provided. If desired, the mark 10 may be read manually using a suitable microscope.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1. A lithographic apparatus arranged to transfer a substrate pattern from a patterning device onto a substrate, comprising a programmable patterning device arranged to transfer a pattern representing a code mark to the substrate.

2. The apparatus according to claim 1, wherein the programmable patterning device is arranged to transfer a pattern representing a code mark comprising a pixel array and a reference marker.

3. The apparatus according to claim 2, wherein the programmable patterning device is arranged to transfer a pattern representing a reference marker located at a predetermined position relative to the pixel array.

4. The apparatus according to claim 2, wherein the programmable patterning device is arranged to transfer a pattern representing four reference markers, two provided on each side of the pixel array.

5. The apparatus according to claim 2, wherein the programmable patterning device is arranged to transfer a pattern representing a reference marker that is substantially the same size and shape as a pixel of the pixel array.

6. The apparatus according to claim 1, wherein the programmable patterning device is arranged to transfer a pattern representing a code mark that has overall dimensions less than about 200 μm on the substrate.

7. The apparatus according to claim 1, wherein the programmable patterning device arranged to transfer the pattern representing a code mark is separate from the patterning device used to transfer the substrate pattern to the substrate.

8. The apparatus according to claim 1, wherein the programmable patterning device arranged to transfer the pattern representing a code mark is the patterning device used to transfer the substrate pattern to the substrate.

9. A device manufacturing method, comprising:
transferring a pattern representing a code mark to a substrate using a programmable patterning device; and
transferring a substrate pattern from a patterning device onto the substrate.

10. The method according to claim 9, wherein the code mark comprises a pixel array and a reference marker.

11. The method according to claim 10, wherein the reference marker is located at a predetermined position relative to the pixel array.

12. The method according to claim 10, wherein the code mark comprises four reference markers, two provided on each side of the pixel array.

13. The method according to claim 10, wherein the reference marker is substantially the same size and shape as a pixel of the pixel array.

14. The method according to claim 9, wherein the code mark has overall dimensions less than about 200 μm on the substrate.

15. The method according to claim 9, wherein the programmable patterning device arranged to transfer the pattern representing the code mark is separate from the patterning device used to transfer the substrate pattern to the substrate.

16. The method according to claim 9, wherein the programmable patterning device arranged to transfer the pattern representing the code mark is the patterning device used to transfer the substrate pattern to the substrate.

17. A code reading device arranged to read a code mark on a substrate, the code mark comprising a pixel array and one or more reference markers.

18. A lithographic apparatus having a code reading device according to claim 17.

19. A process apparatus having a code reading device according to claim 17.

20. A measurement apparatus having a code reading device according to claim 17.

21. A substrate having printed thereon a code mark comprising a pixel array and one or more reference markers.

22. The substrate according to claim 21, wherein the code mark comprises four reference markers, two provided on each side of the pixel array.

23. The substrate according to claim 21, wherein the code mark comprises a reference mark that is substantially the same size and shape as a pixel of the pixel array.

24. The substrate according to claim 21, wherein the code mark has overall dimensions less than about 200 μm on the substrate.
